(19) United States
(12) Patent Application Publication
(10) Pub. No.: US 2023/0269921 A1
(43) Pub. Date: Aug. 24, 2023

(54) FILM STICKING TOOL

(71) Applicant: Shenzhen Momi Electronic Technology Co., LTD., Shenzhen (CN)

(72) Inventor: Shengjie Zhou, Shenzhen (CN)

(21) Appl. No.: 17/676,441

(22) Filed: Feb. 21, 2022

(51) Int. Cl. H05K 13/04; H05K 13/00

(52) U.S. Cl. CPC H05K 13/04; H05K 13/0015; G06F 1/1656

(57) ABSTRACT

Disclosed is a film sticking tool. The film sticking tool includes a base, a mounting seat and a pressing member. The base is provided with a sliding groove, the sliding groove having a first opening that opens toward one side; the mounting seat is provided with a positioning groove, the positioning groove being configured for positioning a device to be stuck with a film, and the mounting seat sliding into the sliding groove from the first opening; and the pressing member is provided close to the first opening and configured for pressing a film onto the device to be stuck with a film when the mounting seat is sliding into the sliding groove. The technical schemes of the present invention are simple in structure and easy to operate, which can easily remove air between the film and the device to be stuck with a film, prolong the service life of the film, and prevent the air between the film and the device to be stuck with a film from affecting the display effect of the device to be stuck with a film.

### TECHNICAL FIELD

The present invention relates to the field of electronic product accessories, and in particular, to a film sticking tool.

### BACKGROUND

With the rapid improvement of people's life, mobile phones, smart watches, tablet computers and other electronic products have become necessary tools for everyone. Film is a kind of plastic film attached to the screen of an electronic product, which can effectively cushion the impact, prevent the screen from bursting, or prevent the glass panel from being broken and scattered due to accidental impact to the electronic product, reduce the potential damage of the glass panel and ensure the safety of users. The film can also maintain the luster and texture of the screen and improve the surface hardness.

Traditional film sticking generally adopts manual film sticking, and when sticking a film on the screen of an electronic product, air is easily left between the film and the screen of the electronic product, thus affecting the display effect of the screen of the electronic product after film sticking.

### SUMMARY OF THE INVENTION

The main objective of the present invention is to provide a film sticking tool, which aims at removing air between a film and a screen of an electronic product.

In order to achieve the above objective, the film sticking tool provided by the present invention includes:

a base provided with a sliding groove, the sliding groove having a first opening that opens toward one side;

a mounting seat provided with a positioning groove, the positioning groove being configured for positioning a device to be stuck with a film, and the mounting seat sliding into the sliding groove from the first opening; and

a pressing member provided close to the first opening and configured for pressing a film onto the device to be stuck with a film when the mounting seat is sliding into the sliding groove.

Optionally, the sliding groove has a second opening that opens upward, and the pressing member is provided at an upper end of the second opening.

Optionally, the film sticking tool further includes a base cover configured for covering the second opening of the base.

Optionally, the base is provided with one support member on each of two opposite sides of the second opening, the pressing member is a roller, and both ends of the roller are rotatably provided on the two support members, respectively.

Optionally, the ends of the roller are gradually thickened in a direction away from a middle of the roller.

Optionally, the mounting base is provided with a film fixing member, and the film fixing member is provided at an end of the mounting base in a sliding direction.

Optionally, the film fixing member includes a first fixing member provided at a front end of the mounting base along the sliding direction, the first fixing member includes a first cover plate and a first post provided on the first cover plate, the mounting base is provided with a slot corresponding to the first post, and the first post is provided in the slot; and/or the film fixing member further includes a second fixing member provided at one end of the mounting base away from the first fixing member, the second fixing member includes a second cover plate, both ends of the second cover plate are provided with a jack, respectively, the mounting base is provided with two second posts corresponding to the two jacks, and the second posts are provided in the jacks.

Optionally, an edge of the second opening is provided with a first limiting rib protruding into the sliding groove; and/or the mounting base is further provided with a guide rib, the guide rib is provided at an edge of a groove wall of the positioning groove and close to the first fixing member, and a side of the guide rib that faces the first fixing member is provided with a guide slope.

Optionally, a bottom wall of the sliding groove is provided with a slide rail, the slide rail extends in the sliding direction of the mounting seat, a bottom surface of the mounting seat is provided with a slideway corresponding to the slide rail, and the slide rail is provided in the slideway; and/or one end of the mounting seat that blocks the first opening is provided with a handle; and/or the end of the mounting seat that blocks the first opening is provided with a second limiting rib extending toward a bottom of the base, and a groove bottom of the sliding groove is provided with an avoidance recess corresponding to the second limiting rib.

Optionally, one end of the groove bottom of the sliding groove close to the first opening is provided with a drawing notch, and the drawing notch is communicated with the avoidance recess.

The film sticking tool at least has the following beneficial effects.

According to the technical schemes of the present invention, a base, a mounting seat and a pressing member is adopted. The base is provided with a sliding groove, and the sliding groove has a first opening that opens toward one side; the mounting seat is provided with a positioning groove configured for positioning the device to be stuck with a film, and the mounting seat slides into the sliding groove from the first opening; the pressing member is provided close to the first opening, and is configured for pressing the film against the device to be stuck with a film when the mounting seat is sliding into the sliding groove. Understandably, the use process of the film sticking tool is as follows: firstly, the device to be stuck with a film is mounted in the positioning groove of the mounting base, then the film is covered on the screen of the device to be stuck with a film, then the mounting base is slid into the sliding groove from the first opening of the base, and the upper surface of the film is pressed by the pressing member, so that air between the film and the device to be stuck with a film is forced to be removed by pressure. Thus the film can be attached to the device to be stuck with a film more tightly, so that the use effect of the device stuck with the film can be increased. And since the air is removed from between the film and the device to be stuck with a film, it is beneficial to prolong the service life of the film, because if the air remains between the film and the device to be stuck with a film, the film is easily separated from the screen of the device to be stuck with a film. It can be seen that the technical schemes of the present invention are simple in structure and easy to operate, which can easily remove air between the film and the device to be stuck with a film, prolong the service life of the film, and prevent the air between the film and the device to be stuck with a film from affecting the display effect of the device to be stuck with a film.

### BRIEF DESCRIPTION OF THE DRAWINGS

In order to describe the embodiments of the present invention or the technical schemes in the prior art more clearly, the following will briefly introduce the accompanying drawings that are to be used in the description of the embodiments or the prior art. Obviously, the accompanying drawings in the following are only some embodiments of the present invention, and for a person of ordinary skill in the art, other drawings can be obtained according to the structures shown in the accompanying drawings without creative efforts.

FIG. 1 is a schematic view from a perspective of an explosion structure of an embodiment of the film sticking tool of the present invention;

FIG. 2 is a schematic view from another perspective of the explosion structure of the film sticking tool of FIG. 1;

FIG. 3 is a schematic view from another perspective of the explosion structure of the film sticking tool of FIG. 1;

FIG. 4 is a schematic view from a perspective of another embodiment of the film sticking tool of the present invention; and

FIG. 5 is a schematic view from another perspective of the explosion structure of the film sticking tool of FIG. 4.

### DESCRIPTION OF REFERENCE NUMERALS

| Numeral | Name | Numeral | Name |
|---|---|---|---|
| 100 | Base | 110 | Sliding groove |
| 111 | First opening | 112 | Second opening |
| 113 | Slide rail | 114 | Avoidance recess |
| 115 | Drawing notch | 120 | Support member |
| 130 | First limiting rib | 200 | Mounting seat |
| 210 | Positioning groove | 220 | Film fixing member |
| 221 | First fixing member | 221a | First cover plate |
| 221b | First post | 222 | Second fixing |
| | | | member |
| 222a | Second cover plate | 222b | Jack |
| 230 | Slot | 240 | Second post |
| 250 | Guide rib | 260 | Slideway |
| 270 | Handle | 280 | Second limiting rib |
| 300 | Pressing member | 400 | Base cover |

The implementation, functional features and advantages of the present invention will be further described with reference to the accompanying drawings in conjunction with the embodiments.

### DETAILED DESCRIPTION

Next, the technical schemes in the embodiments of the present invention will be clearly and completely described with reference to the drawings in the embodiments of the present invention. Obviously, the described embodiments are only part of the embodiments of the present invention, not all thereof. Based on the embodiments in the present invention, all other embodiments obtained by a person of ordinary skill in the art without creative efforts hall fall within the protection scope of the present invention.

It should be noted that all directional indications (such as up, down, left, right, front, back, . . . ) in the embodiments of the present invention are only intended to explain the relative positional relationship, movement situation, and the like among components in a certain posture (as shown in the accompanying drawings), and if the specific posture changes, the directional indications will change accordingly.

In the present invention, unless otherwise clearly specified and limited, the terms “connected”, “fixed”, and the like should be understood in a broad sense. For example, “fixed” can mean a fixed connection, a detachable connection, or a whole; it can mean a mechanical connection or an electrical connection; it can mean direct connection or indirect connection through an intermediate medium; and it can mean internal communication between two elements or an interaction relationship between two elements, unless otherwise explicitly limited. For a person of ordinary skill in the art, the specific meanings of the above-mentioned terms in the present invention can be understood according to specific circumstances.

In addition, if there are descriptions related to “first” and “second” in the embodiments of the present invention, the descriptions of the “first” and “second” are only configured for the objective of description, and cannot be understood as indicating or implying their relative importance or implicitly indicating the number of indicated technical features. Therefore, the features defined with “first” and “second” may explicitly or implicitly include at least one of the features. In addition, the meaning of “and/or” appears in the text includes three parallel schemes, for example, “A and/or B” includes scheme A, scheme B, or a scheme including both scheme A and scheme B. In addition, the technical schemes among the various embodiments may be combined with each other, but they must be based on the implementation by a person of ordinary skill in the art. When the combination of technical schemes is contradictory or impossible to implement, it should be considered that such a combination of technical schemes does not exist, nor is it within the protection scope claimed by the present invention.

The present invention provides a film sticking tool.

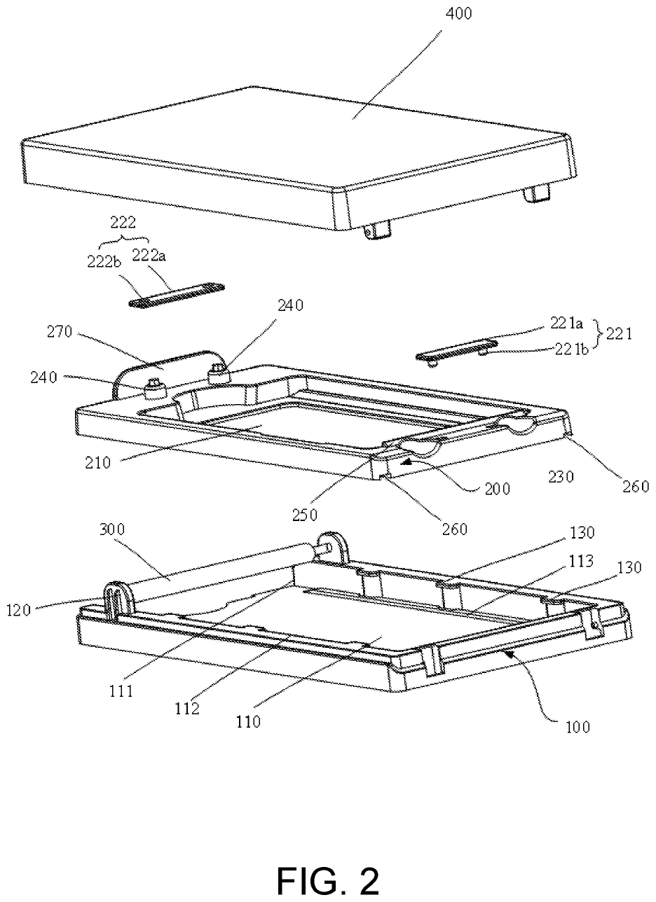

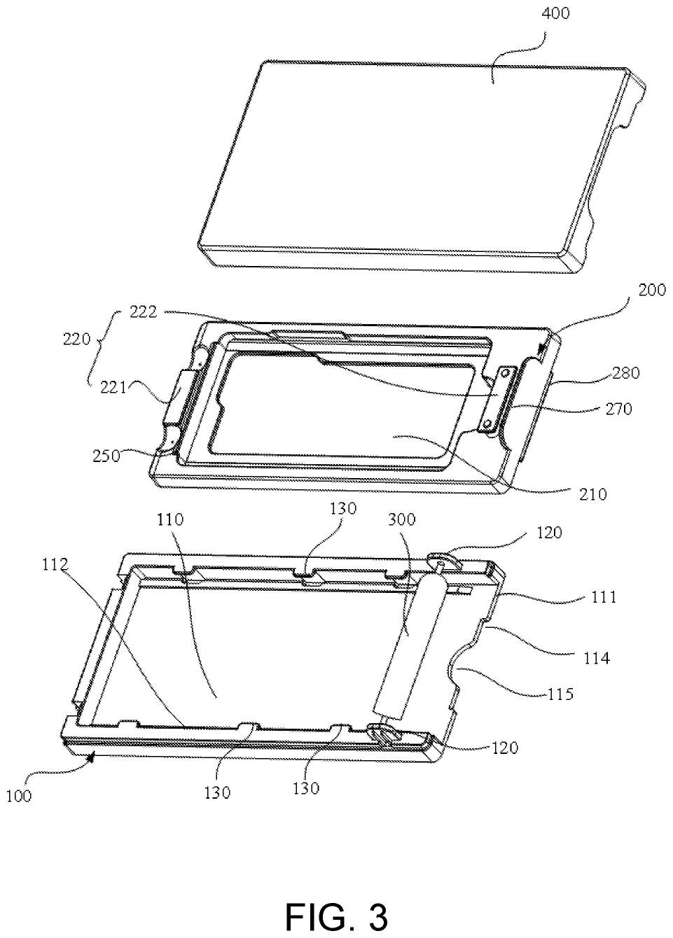

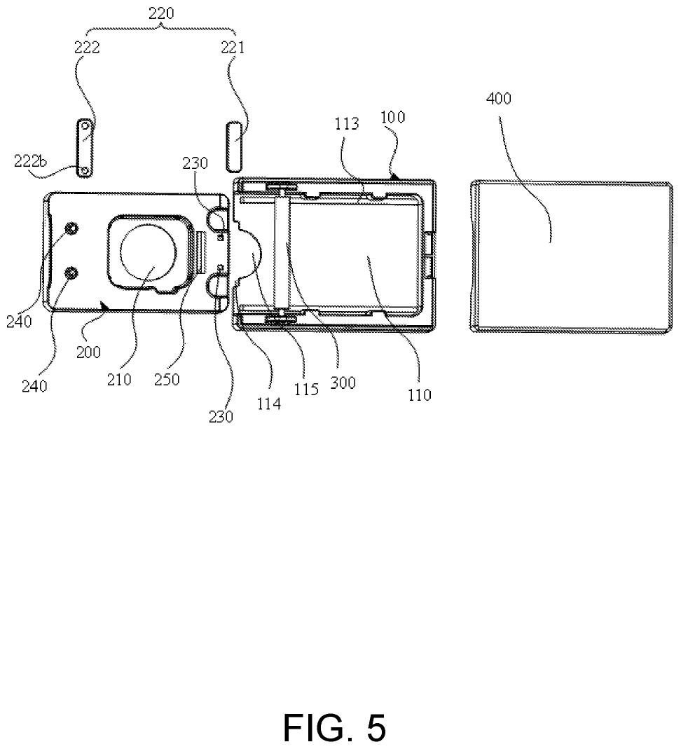

Referring to FIGS. 2, 3 and 5, in one embodiment of the present invention, the film sticking tool includes a base 100, a mounting base 200 and a pressing member 300. The base 100 is provided with a sliding groove 110 having a first opening 111 that opens toward one side. The mounting base 200 is provided with a positioning groove 210 for positioning the device to be stuck with a film, and the mounting base 200 slides into the sliding groove 110 from the first opening 111. The pressing member 300 is provided close to the first opening 111, and is configured to press the film onto the device to be stuck with a film when the mounting base 200 is sliding into the sliding groove 110.

Specifically, in one embodiment, the use process of the film sticking tool is as follows: firstly, the device to be stuck with a film is mounted in the positioning groove 210 of the mounting base 200, then the film is covered on the screen of the device to be stuck with a film, then the mounting base 200 is slid into the sliding groove 110 from the first opening 111 of the base 100, and the upper surface of the film is pressed by the pressing member 300, so that air between the film and the device to be stuck with a film is forced to be removed by pressure. Thus the film can be attached to the device to be stuck with a film more tightly, so that the use effect of the device stuck with the film can be increased. And since the air is removed from between the film and the device to be stuck with a film, it is beneficial to prolong the service life of the film, because if the air remains between the film and the device to be stuck with a film, the film is easily separated from the screen of the device to be stuck with a film. It can be seen that the technical schemes of the present invention are simple in structure and easy to operate, which can easily remove air between the film and the device to be stuck with a film, prolong the service life of the film, and prevent the air between the film and the device to be stuck with a film from affecting the display effect of the device to be stuck with a film.

Further, the film mentioned in this technical scheme can be a high-definition film, a frosted film, a mirror film, a diamond film, a peep-proof film, a scratch-proof film and other film, and the functions of the film are not specifically limited here.

Further, the material of the film can be PP (polypropylene), PVC (polyvinyl chloride), PET (polyethylene terephthalate, commonly known as polyester resin), TPU (thermoplastic polyurethane elastomer rubber), glass (such as but not limited to tempered glass) and other material, and the material of the film is not specifically limited here.

In another embodiment, the base 100 may only be provided with a bottom plate, and the upper surface of the bottom plate is provided with a guide structure (such as a rib or a groove, which is not specifically limited here) for guiding the mounting seat 200 to slide in a fixed direction. The upper end of the bottom plate is provided with a pressing member 300 perpendicular to the sliding direction of the mounting seat 200, and the pressing member 300 is spaced apart from the bottom plate. When the mounting seat 200 slides along the guide structure, the pressing member 300 just presses the film, making the film pressed onto the device to be stuck with a film.

Further, the mounting base 200 is provided with an avoidance groove which is communicated with the positioning groove 210. When positioning the device to be stuck with a film, the function keys of the device to be stuck with a film are placed in the avoidance groove. The arrangement of the avoidance groove can prevent the groove wall of the positioning groove 210 from squeezing the function keys of the device to be stuck with a film for a long time, which may affect the service life of the function keys of the device to be stuck with a film.

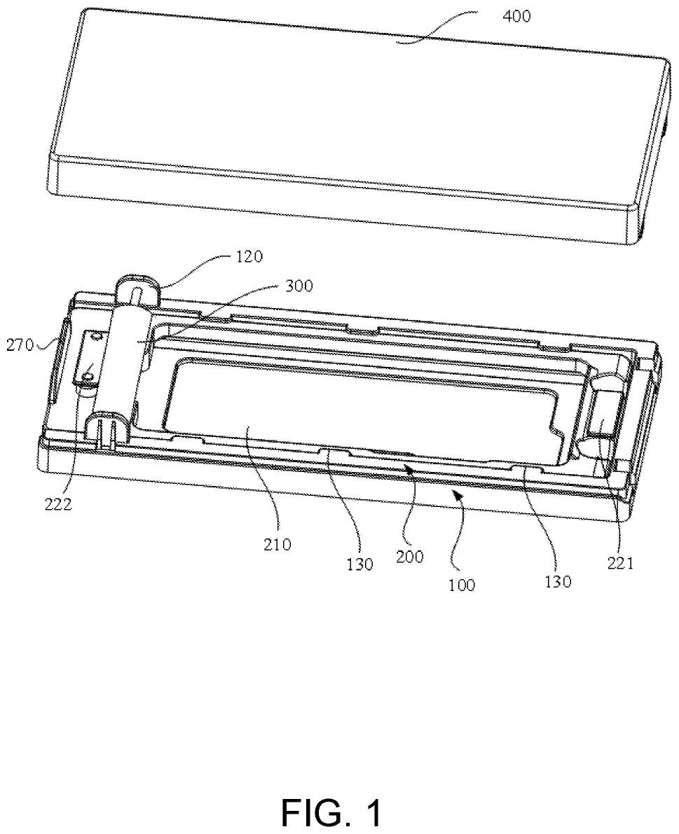

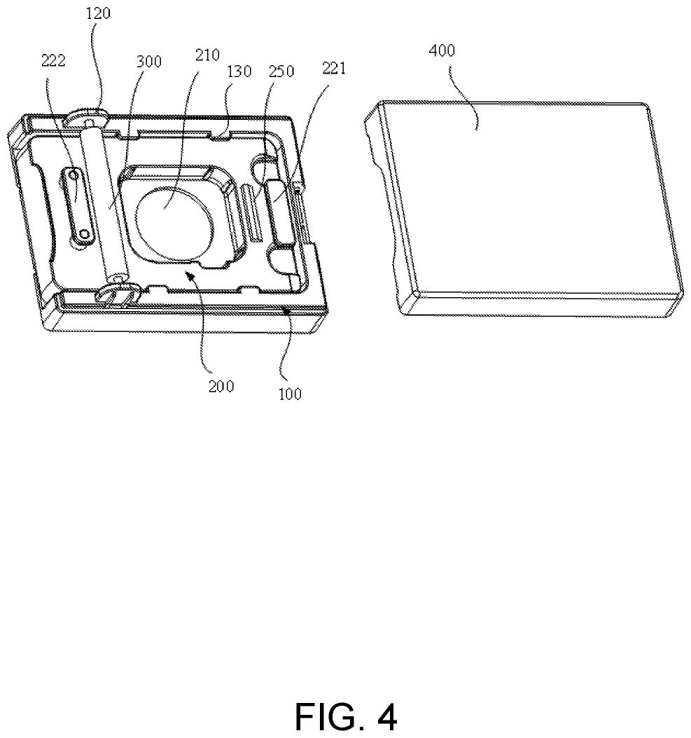

According to FIGS. 1 and 4, further, the device to be stuck with a film can be a mobile phone or a smart watch. FIG. 1 is a diagram of a film sticking tool for a mobile phone, and FIG. 4 is a diagram of a film sticking tool for a smart watch. The device to be stuck with a film is not specifically limited here.

Referring to FIGS. 2, 3 and 5, optionally, the sliding groove 110 has a second opening 112 that opens upward, and the pressing member 300 is provided on the upper end of the second opening 112. It can be understood that the user can view the sticking situation of the device to be stuck with a film in real time through the second opening 112, for example, but not limited to this, if the film is misplaced, the user can be aware of it in time, so that adjustments can be made in time. Of course, the present invention is not limited to this. In other embodiments, the pressing member 300 may also be provided at the front end of the first opening 111.

Optionally, the base 100 is provided with a support member 120 on two opposite sides of the second opening 112, the pressing member 300 is a roller, and both ends of the roller are rotatably provided on the two support members 120, respectively. The roller rolls on the surface of the film, so that the mounting base 200 can slide into the sliding groove 110 more smoothly, and the air between the film and the device to be stuck with a film sticking can be removed by the pressure of the roller rolling on the surface of the film, which can prevent the pressing member 300 from damaging the screen of the device to be stuck with a film. Of course, the present invention is not limited to this. In the second embodiment, the pressing member 300 can also be a pressing plate, and the opposite side of the pressing plate is fixed on the support member 120. Specifically, elastic silica gel can be provided at the side where the pressing plate is pressed against the film or at the joint between the pressing plate and the support member 120, so that the pressing plate can have a certain elastic shrinkage range.

Further, in one embodiment, there may be one roller, and in the second embodiment, there may be two rollers. Here, the number of rollers is not specifically limited, and can be provided according to specific circumstances.

Further, the support member 120 is provided with rotation grooves, and both ends of the roller are rotatably provided in the two rotation grooves, respectively. Of course, the present invention is not limited to this. In other embodiments, the roller can also be rotatably provided on the support member 120 through a bearing. Further, the support member 120 can be a support plate or a support column, which is not specifically limited here.

Further, the film used for the film tool provided in this technical scheme can be not only a plane film but also a curved film. The end of the roller is gradually thickened in the direction away from the middle, which can make the roller adapt to the curved mobile phone, make the curved film stick to the curved screen device more tightly, and make the use of the film sticking tool more flexible.

Further, the film sticking tool can be provided with two types of rollers, one is a straight roller with a constant cross-sectional area, and the other is a side curved roller whose end is gradually thickened in the direction away from the middle. The user can choose an appropriate roller according to the situation. If the device to be stuck with a film has a plane screen, we can choose a straight roller, and when the device to be stuck with a film has a curved surface screen, we can choose a side curved roller to increase the flexibility of the film sticking tool.

Optionally, the mounting base 200 is provided with a film fixing member 220, the film fixing member 220 is provided at the end of the mounting base 200 in the sliding direction. The arrangement of the film fixing member 220 is beneficia to fix the film with the fixing part of the film, so as to avoid the film from deviating from the device to be stuck with a film and damaging the film or affecting the film effect. Of course, the present invention is not limited to this. In other embodiments, fixing structures may be provided at the sides of the mounting base 200 in the sliding direction and the vertical sliding direction.

Optionally, the film fixing member 220 includes a first fixing member 221 provided at the front end of the mounting base 200 along the sliding direction, and the first fixing member 221 includes a first cover plate 221a and a first post 221b provided on the first cover plate 221a. The mounting base 200 is provided with a slot 230 corresponding to the first post 221b, and the first post 221b is provided in the slot 230. It can be understood that such a first fixing member 221 is provided on the groove top surface of the positioning groove 210, which is beneficial to pull the film downward, facilitate the film to smoothly pass through the bottom surface of the pressing member 300, and prevent the end of the film and the pressing member 300 from blocking each other. When fixing the film, firstly the first post 221b is inserted into the fixing hole of the film, and then the first post 221b is inserted into the slot 230 to fix the film, which is easy to operate and beneficial to improve the fixing speed of the film, thus improving the film sticking speed of the device to be stuck with a film. Of course, the present invention is not limited to this. In other embodiments, the first post 221b may be provided on the mounting base 200, while the first cover plate 221a may be provided with a slot 230, and the first post 221b may be provided in the slot 230.

Optionally, the film fixing member 220 further includes a second fixing member 222 provided at one end of the mounting base 200 which is away from the first fixing member 221. The second fixing member 222 includes a second cover plate 222a, and both ends of the second cover plate 222a are provided with a jack 222b, respectively. The mounting base 200 is provided with two second post posts 240 corresponding to the two jacks 222b, and the second post posts 240 are provided in the jacks 222b. It can be understood that when fixing the film, the second posts 240 is first inserted into the fixing hole of the film, and then the second posts 240 is inserted into the jacks 222b, so that the film can be fixed, and the operation is simple, which is beneficial to improve the fixing speed of the film and the sticking speed of the device to be stuck with a film. Of course, the present invention is not limited to this. In other embodiments, the second posts 240 may be provided on the second cover plate 222a, while the jacks 222b may be provided on the mounting base 200, and the second posts 240 may be provided in the jacks 222b.

Optionally, the edge of the second opening 112 is provided with a first limiting rib 130 protruding into the sliding groove 110; and/or, the mounting base 200 is further provided with a guide rib 250, the guide rib 250 is provided at the edge of the groove wall of the positioning groove 210 and close to the first fixing member 221, and the side of the guide rib 250 that faces the first fixing member 221 is provided with a guide slope.

It should be noted that the edge of the second opening 112 is provided with the first limiting rib 130 protruding into the sliding groove 110 to prevent the mounting seat 200 from tilting upward when it is sliding into the sliding groove 110, so that the mounting seat 200 can slide forward smoothly and increase the stability of the film sticking process. In one embodiment, a plurality of first limiting ribs 130 can be provided, and the plurality of first limiting ribs 130 are provided at intervals at the edge of the second opening 112. Of course, the present invention is not limited to this. In other embodiments, there may be one first limiting rib 130 extending in the sliding direction of the mounting base 200.

Further, the mounting base 200 is further provided with a guide rib 250, the guide rib 250 is provided at the edge of the groove wall of the positioning groove 210 and close to the first fixing member 221. The side of the guide rib 250 that faces the first fixing member 221 is provided with a guide slope, so that the film can be guided to incline downwards, and when the mounting base 200 slides, it can facilitate the film to smoothly pass through the bottom surface of the pressing member 300, thus preventing the end of the film and the pressing member 300 from blocking each other and affecting the efficiency of the film sticking.

Optionally, a slide rail 113 is provided on the bottom wall of the sliding groove 110, and the slideway 113 extends in the sliding direction of the mounting seat 200. The bottom surface of the mounting seat 200 is provided with a slide rail 260 corresponding to the slideway 113, and the slide rail 113 is provided in the slide rail 260. The matching of the slide rail 113 and the slideway 260 is simple in structure, convenient for processing, and beneficial to make the mounting seat 200 stably slide along the slide rail 113, thus avoiding inclination. Of course, the present invention is not limited to this. In the second embodiment, the bottom wall of the sliding groove 110 may be provided with a concave chute, and the bottom surface of the mounting base 200 may be provided with a pulley corresponding to the chute, and the pulley may be provided in the chute. Of course, the present invention is not limited to this. In the third embodiment, the slideway 113 is provided on the bottom surface of the mounting base 200, and the slide rail 113 extends in the sliding direction of the mounting base 200. The bottom wall of the sliding groove 110 is provided with a slide rail 260 corresponding to the slideway 113, and the slide rail 113 is provided in the slide rail 260.

Optionally, one end of the mounting base 200 that blocks the first opening 111 is provided with a handle 270. The arrangement of the handle 270 is convenient for the user to hold the mounting base 200, and there is a force point on the mounting base 200, which is convenient for pushing and pulling the mounting base 200. In one embodiment, the handle 270 is a rib extending to the upper end of the positioning groove 210. Of course, the present invention is not limited to this. In the second embodiment, the handle 270 may also be a rib extending in the sliding direction of the mounting base 200. Of course, the present invention is not limited to this. In the third embodiment, the handle 270 may also be a bent handle extending in the sliding direction of the mounting base 200.

Optionally, one end of the mounting seat 200 that blocks the first opening 111 is provided with a second limiting rib 280 extending toward the bottom of the base 100, and the groove bottom of the sliding groove 110 is provided with an avoidance recess 114 corresponding to the second limiting rib 280. The arrangement of the second limiting rib 280 can prevent the mounting seat 200 from sliding into the sliding groove 110 excessively, and prevent the groove wall of the sliding groove 110 from colliding with the mounting seat 200, thus affecting the device to be stuck with a film. Of course, the present invention is not limited to this. In other embodiments, the avoidance recess 114 may not be provided at the bottom of the sliding groove 110, but the second limiting rib 280 and the edge of the first opening 111 of the sliding groove 110 may form a limiting structure

Optionally, one end of the bottom of the sliding groove 110 that is close to the first opening 111 is provided with a drawing notch 115, and the drawing notch 115 is communicated with the avoidance recess 114. The arrangement of the drawing notch 115 is convenient for the user to hold the mounting base 200 through the drawing notch 115 and pull out the mounting base 200.

Optionally, the film sticking tool further includes a base cover 400 for covering the second opening 112 of the base 100. The arrangement of the base cover 400 is beneficial to prevent impurities such as dust from adhering to the mounting base 200, the base 100 and the pressing member 300, thereby preventing impurities from affecting the film sticking effect.

Further, the base cover 400 is made of a transparent material, such as glass, transparent plastic and other material, and the specific material is not limited here. The transparent material may enable viewing of the whole film sticking process even when the base cover 400 is covering the base 100.

Optionally, the base cover 400 is rotatably connected to one end of the base 100 that is away from the first opening 111. That the base cover 400 is rotatably provided on the base 100, on the one hand, can avoid the base cover 400 from being lost when it is detached from the base 100, on the other hand, can improve the efficiency of receiving the film sticking tool, and only one turning action is needed to cover the base cover 400 on the base 100. Of course, the present invention is not limited to this. In other embodiments, the base cover 400 can also be snapped on the base 100.

The above are only descriptions for optional embodiments of the present invention, and shall not limit the protection scope of the present invention. Under the inventive concept of the present invention, any equivalent structural transformation made by using the contents of the description and drawings of the present invention or direct/indirect application thereof in other related technical fields shall fall within the patent protection scope of the present invention.

I claim:

1. A film sticking tool, comprising: a base provided with a sliding groove, the sliding groove having a first opening that opens toward one side; a mounting seat provided with a positioning groove, the positioning groove being configured for positioning a device to be stuck with a film, and the mounting seat sliding into the sliding groove from the first opening; and a pressing member provided close to the first opening and configured for pressing a film onto the device to be stuck with a film when the mounting seat is sliding into the sliding groove.

2. The film sticking tool of claim 1, wherein the sliding groove has a second opening that opens upward, and the pressing member is provided at an upper end of the second opening.

3. The film sticking tool of claim 2, further comprising a base cover configured for covering the second opening of the base.

4. The film sticking tool of claim 2, wherein the base is provided with one support member on each of two opposite sides of the second opening, the pressing member is a roller, and both ends of the roller are rotatably provided on the two support members, respectively.

5. The film sticking tool of claim 4, wherein the ends of the roller are gradually thickened in a direction away from a middle of the roller.

6. The film sticking tool of claim 2, wherein the mounting base is provided with a film fixing member, and the film fixing member is provided at an end of the mounting base in a sliding direction.

7. The film sticking tool of claim 6, wherein the film fixing member comprises a first fixing member provided at a front end of the mounting base along the sliding direction, the first fixing member comprises a first cover plate and a first post provided on the first cover plate, the mounting base is provided with a slot corresponding to the first post, and the first post is provided in the slot; and/or the film fixing member further comprises a second fixing member provided at one end of the mounting base away from the first fixing member, the second fixing member comprises a second cover plate, both ends of the second cover plate are provided with a jack, respectively, the mounting base is provided with two second posts corresponding to the two jacks, and the second posts are provided in the jacks.

8. The film sticking tool of claim 7, wherein an edge of the second opening is provided with a first limiting rib protruding into the sliding groove; and/or the mounting base is further provided with a guide rib, the guide rib is provided at an edge of a groove wall of the positioning groove and close to the first fixing member, and a side of the guide rib that faces the first fixing member is provided with a guide slope.

9. The film sticking tool of any one of claims 1 to 8, wherein a bottom wall of the sliding groove is provided with a slide rail, the slide rail extends in the sliding direction of the mounting seat, a bottom surface of the mounting seat is provided with a slideway corresponding to the slide rail, and the slide rail is provided in the slideway; and/or one end of the mounting seat that blocks the first opening is provided with a handle; and/or the end of the mounting seat that blocks the first opening is provided with a second limiting rib extending toward a bottom of the base, and a groove bottom of the sliding groove is provided with an avoidance recess corresponding to the second limiting rib.

10. The film sticking tool of claim 9, wherein one end of the groove bottom of the sliding groove close to the first opening is provided with a drawing notch, and the drawing notch is communicated with the avoidance recess.
